(19) United States
(12) Patent Application Publication
(10) Pub. No.: US 2024/0301162 A1
(43) Pub. Date: Sep. 12, 2024

(54) POLYBUTYLENE TEREPHTHALATE COMPOSITION AND ARTICLE

(71) Applicant: BASF SE, Ludwigshafen (DE)

(72) Inventors: Li Xia Wang, Shanghai (CN); Zhen Ke Wei, Shanghai (CN); Tao Liu, Shanghai (CN); Li Rong He, Shanghai (CN)

(21) Appl. No.: 18/558,431

(22) PCT Filed: Apr. 27, 2022
(86) PCT No.: PCT/EP2022/061184

§ 371 Date: Nov. 1, 2023

(30) Foreign Application Priority Data
May 7, 2021 (WO) PCT/CN2021/092116

(51) Int. Cl. C08K 3/04; C08K 7/14

(52) U.S. Cl. CPC C08K 3/041; C08K 7/14; C08K 2201/001; C08K 2201/011

(57) ABSTRACT

The present invention relates to a polybutylene terephthalate composition, comprising (A) 40 to 99.8% by weight of polybutylene terephthalate, (B) 0.2 to 10% by weight of at least one conductive filler selected from the group consisting of carbon nanotubes, carbon nanostructures, and a combination thereof, and (C) 0 to 50% by weight of glass fiber, each being based on the total weight of the poly butylene terephthalate composition, wherein the carbon nanostructures each comprise a plurality of carbon nanotubes which are branched, crosslinked, and/or sharing common walls with one another. The present invention also relates to an EMI shielding article produced from the polybutylene terephthalate composition.

### FIELD OF THE INVENTION

The present invention relates to a polybutylene terephthalate (PBT) composition, and an article produced from the same.

### BACKGROUND OF THE INVENTION

In recent decades, electronic devices played an increasingly essential role in various fields and the amounts thereof increased dramatically. Electromagnetic interference (EMI) has always been a problem accompanying the electronic devices. In order to prevent or reduce harmful influence of the electromagnetic interference between different electronic parts in an electronic device or between an electronic device with environments, a housing is generally used as a barrier. In certain fields, the housing is made of plastic composite materials, for example filled plastic shielding composite materials. Typically, the filled plastic shielding composite materials consist of a thermoplastic polymer matrix, an electromagnetic absorbing filler, and optionally additional additives.

A variety of thermoplastic polymers can be used as the matrix of the filled plastic shielding composite materials depending on the particular application fields, for example polyesters such as polyethylene terephthalate (PET) and polybutylene terephthalate (PBT), polycarbonates, copolyester-carbonates, polyarylene ether sulfones and ketones, polyamides, polyamide-imides, polystyrenes, acrylonitrile-butadiene-styrene copolymers, polyetherimides and polyphenylene ethers.

Electromagnetic absorbing filler useful in the filled plastic shielding composite materials are desirably electrically conductive. Metal powders were initially used as the electromagnetic absorbing filler. With the developments of the filled plastic shielding composite materials, carbon materials such as carbon black, graphite, graphene, carbon fiber, and carbon nanotube (CNT) have been proposed for their excellent overall performance with respect to EMI shielding efficiency, electric conductivity, thermal conductivity and the mechanical property.

For example, JP2014133842A describes an electromagnetic shielding conductive resin composition comprising a thermoplastic resin and carbon nanotubes, carbon black and carbon fibers, and having a volume resistivity of 1×10² Ω·cm or less. The thermoplastic resin can be olefin resins, acrylic resins, styrene resins, vinyl resins, polyesters, polyamides, polyimides, polyetherimide, polycarbonate, polyacetal, polyethersulfone, polyphenylene oxide, polyphenylene sulfide, polysulfone, polyurethane, etc.

WO2003085681A1 describes an electromagnetic shielding composition comprising a polymeric foam and about 0.0001 to about 50 wt % carbon nanotubes, and having a volume resistivity of about 10⁻³ to about 10⁸ Ω·cm, wherein the polymeric foam comprises polyacetal, polyacrylic, styrene acrylonitrile, acrylonitrile-butadiene-styrene, polycarbonate, polystyrene, polyethylene, polypropylene, polyethylene terephthalate, polybutylene terephthalate, polyamide, polyamideimide, polyarylate, polyurethane, ethylene propylene diene monomer rubber, ethylene propylene rubber, polyarylsulfone, polyethersulfone, polyarylene sulfide, polyvinyl chloride, polysulfone, polyetherimide, polytetrafluoroethylene, fluorinated ethylene propylene, polychlorotrifluoroethylene, polyvinylidene fluoride, polyvinyl fluoride, polyetherketone, polyether etherketone, polyether ketone ketone, natural rubber, synthetic rubber, epoxy, phenolic, polyester, polyamide, silicone, or a combination comprising at least one of the foregoing polymers.

However, there is still a continuing need to provide filled plastic composite materials having a desirable EMI shielding efficiency, especially in the radome application.

### SUMMARY OF THE INVENTION

The object of the present invention is to provide a polybutylene terephthalate (PBT) composition having a desirable EMI shielding efficiency.

Accordingly, the present invention provides a polybutylene terephthalate composition, comprising
(A) 40 to 99.8% by weight of polybutylene terephthalate,
(B) 0.2 to 10% by weight of at least one conductive filler selected from the group consisting of carbon nanotubes, carbon nanostructures, and a combination thereof, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another.

The present invention also provides an EMI shielding article produced from the polybutylene terephthalate composition as described herein.

It has been found that a polybutylene terephthalate composition having a desirable EMI shielding efficiency was provided when carbon nanotubes and/or carbon nanostructures were used as the conductive filler therein. Articles having a desirable EMI shielding efficiency have been produced from the EMI shielding PBT composition according to the present invention.

It has also been found that the carbon nanostructures are particularly useful as the conductive filler in an EMI shielding PBT composition.

### DETAILED DESCRIPTION OF THE INVENTION

The present invention will be described in detail hereinafter. It is to be understood that the present invention can be embodied in many different ways and shall not be construed as limited to the embodiments set forth herein.

The singular forms “a”, “an” and “the” include plural referents unless the context clearly dictates otherwise. The terms “comprise”, “comprising”, etc. are used interchangeably with “contain”, “containing”, etc. and are to be interpreted in a non-limiting, open manner. That is, e.g., further components or elements can be present. The expressions “consists of” or “consists essentially of” or cognates can be embraced within “comprises” or cognates.

The terms “polybutylene terephthalate” and “polybutylene terephthalate composition” herein can also be referred to as “PBT” and “PBT composition” as abbreviations respectively.

The term “fiber material” refers to any material which has fiber as its elementary structural component. The term encompasses fibers, filaments, yarns, tows, tapes, woven and non-woven fabrics, plies, mats, and the like.

The term “spoolable dimensions” refers to fiber materials having at least one dimension that is not limited in length, allowing for the material to be stored on a spool or mandrel. Processes of described herein can operate readily with 5 to 20 lb. spools, although larger spools are usable. Moreover, a pre-process operation can be incorporated that divides very large spoolable lengths, for example 100 lb. or more, into easy to handle dimensions, such as two 50 lb. spools.

The term “transition metal” refers to any element or alloy of elements in the d-block of the periodic table. The term “transition metal” also includes salt forms of the base transition metal element such as oxides, carbides, nitrides, and the like.

The term “material residence time” refers to the amount of time that a discrete point along a fiber material of spoolable dimensions is exposed to CNT growth conditions during the CNS processes described herein. This definition includes the residence time when employing multiple CNT growth chambers.

The term “linespeed” refers to the speed at which a fiber material of spoolable dimensions is fed through the CNT synthesis processes described herein, where linespeed is a velocity determined by dividing CNT chamber(s)′ length by the material residence time.

### Component (A)

PBT is known as a crystalline or semicrystalline thermoplastic polymeric material, for example derived from polycondensation of 1,4-butanediol with terephthalic acid via esterification or with an ester of terephthalic acid via transesterification.

There is no particular restriction to the PBT useful in the polybutylene terephthalate composition according to the present invention. Generally, suitable PBTs can have a weight average molecular weight (Mw) of from 60,000 to 100,000 as measured by gel permeation chromatography. Additionally or alternatively, suitable PBTs can have an intrinsic viscosity in the range from 0.60 to 1.30 dL/g, preferably from 0.60 to 0.90 dL/g, more preferably from 0.60 to 0.80 dL/g, as measured in a 0.005 g/ml phenol/1,2-dichlorobenzene solution (1:1 mass ratio), according to ISO 1628-5.

Any PBTs prepared via known processes or any commercially available PBT materials suitable as engineering plastics can be used for the purpose of the present invention. Examples of commercially available PBT materials include, but are not limited to, Ultradur® series from BASF, such as Ultradur® B1950 Nat, Ultradur® B2550/B2550 FC, Ultradur® B4500/B4500 FC, Ultradur® B4520, Ultradur® B4520 FC Aqua®, Ultradur® B4560, BLUESTAR® series from Bluestar, Crastin® series from DuPont, Pocan® series from Lanxess, NOVADURAN® series from Mitsubishi, LNP™ LUBRICOMP™ series and VALOX™ series from SABIC, RAMSTER® series from Polyram, and Toraycon® series from Toray.

It is preferred that the component (A) is present in the PBT composition according to the present invention in an amount of 50 to 99% by weight, for example, 60 to 99% by weight, 60 to 80% by weight, or 85 to 99% by weight, based on the total weight of the PBT composition.

It is to be understood that the amount of the component (A) when mentioned herein is intended to refer to the amount of PBT per se. Commercially available PBT materials often have been already intentionally added with certain additive(s) to provide at least one desired property such as color, strength, stability and the like, which additive(s) will not be accounted in the amount of the component (A).

### Component (B)

The PBT composition according to the present invention can comprise carbon nanotubes, carbon nanostructures, or a combination thereof. The carbon nanotubes and carbon nanostructures can function as conductive fillers in the PBT composition.

Carbon nanotubes (CNTs) are known in the art, which are allotropes of carbon with a cylindrical nanostructure and are members of the fullerene structural family. Carbon nanotubes have hollow structure with the walls formed by sheets of carbon, i.e. by graphene. These sheets are rolled at specific and discrete (“chiral”) angles, and the combination of the rolling angle and radius decides the nanotube properties, for example, whether the individual nanotube shell shows a metal or semiconductor behavior. Carbon nanotubes are generally categorized as single-walled carbon nanotubes (SWNTs) and multi-walled carbon nanotubes (MWNTs).

The useful CNTs in the PBT composition according to the present invention can be prepared by any known processes, for example arc discharge, laser ablation, high pressure CO conversion, plasma torch, aerosol synthesis, chemical vapor deposition (CVD), etc.

Examples of commercially available CNTs include, but are not limited to, Carbon Nanotube GC30 commercially available from Shandong Dazhan Nano Materials Co., Ltd.

For the purpose of the present invention, CNTs having a diameter of from 1 to 20 nm, in particular from 5 to 10 nm are preferable. Additionally or alternatively, The CNTs particularly have an aspect ratio, i.e., the ratio of length to diameter, of at least 5, preferably at least 10. In preferred embodiments, CNTs have a length of from 1 μm to 500 μm, for example 10 μm to 300 μm, 30 μm to 200 μm, or 50 μm to 150 μm.

Carbon nanostructures refer to a known type of carbon materials which comprise a plurality of carbon nanotubes, wherein the carbon nanotubes are branched, crosslinked, and/or sharing common walls with one another. Particularly, at least a portion of the carbon nanotubes in each carbon nanostructure are aligned substantially parallel to one another. It is to be further understood that every carbon nanotube in the carbon nanostructure need not necessarily be branched, crosslinked, or share common walls with other carbon nanotubes. For example, in some embodiments, at least a portion of the carbon nanotubes in the carbon nanostructure can be interdigitated with one another and/or with branched, crosslinked, or common-wall carbon nanotubes in the remainder of the carbon nanostructure.

Suitable carbon nanostructures include those as described for example in US2016/0362542A1 and US 2014/0099493A1, both of which are incorporated herein by reference.

The carbon nanostructures can be prepared by a method comprising synthesizing nanotubes on growth substrate from a catalyst, and then removing the carbon nanostructure from the growth substrate once synthesis of the carbon nanostructure is completed, as described in US2016/0362542A1.

In some embodiments, the carbon nanostructure can be grown on the growth substrate from a catalyst that includes a plurality of transition metal nanoparticles, as generally described hereinbelow. In some embodiments, one mode for catalyst application onto the growth substrate can be through particle adsorption, such as through direct catalyst application using a liquid or colloidal precursor-based deposition. Suitable transition metal nanoparticle catalysts can include any d-block transition metal or d-block transition metal salt. In some embodiments, a transition metal salt can be applied to the growth substrate without thermal treatments. In other embodiments, a transition metal salt can be converted into a zero-valent transition metal on the growth substrate through a thermal treatment.

In some embodiments, the provision(s) for removing the carbon nanostructure from the growth substrate can include one or more techniques selected from the group consisting of: (i) providing an anti-adhesive coating on the growth substrate, (ii) providing an anti-adhesive coating on a transition metal nanoparticle catalyst employed in synthesizing the carbon nanostructure, (iii) providing a transition metal nanoparticle catalyst with a counter ion that etches the growth substrate, thereby weakening the adherence of the carbon nanostructure to the growth substrate, and (iv) conducting an etching operation after carbon nanostructure synthesis is complete to weaken adherence of the carbon nanostructure to the growth substrate. Combinations of these techniques can also be used. In combination with these techniques, various fluid shearing or mechanical shearing operations can be carried out to affect the removal of the carbon nanostructure from the growth substrate.

In some embodiments, removing a carbon nanostructure from a growth substrate can include using a high pressure liquid or gas to separate the carbon nanostructure from the growth substrate, separating contaminants derived from the growth substrate (e.g., fragmented growth substrate) from the carbon nanostructure, collecting the carbon nanostructure with air or from a liquid medium with the aid of a filter medium, and isolating the carbon nanostructure from the filter medium. In various embodiments, separating contaminants derived from the growth substrate from the carbon nanostructure can take place by a technique selected from the group consisting of cyclone filtering, density separation, size-based separation, and any combination thereof. The foregoing processes are described in more detail hereinbelow.

In some embodiments, the growth substrate can be modified to promote removal of a carbon nanostructure therefrom. In some embodiments, the growth substrate used for producing a carbon nanostructure can be modified to include an anti-adhesive coating that limits adherence of the carbon nanostructure to the growth substrate. The anti-adhesive coating can include a sizing that is commercially applied to the growth substrate, or the anti-adhesive coating can be applied after receipt of the growth substrate. In some embodiments, a sizing can be removed from the growth substrate prior to applying an anti-adhesive coating. In other embodiments, a sizing can be applied to a growth substrate in which a sizing is present.

The growth substrate could be glass, ceramic, metal and organic polymer substrate, and all these are merely exemplary. The organic polymer could be aramid, basalt fiber, or carbon, for example. In some embodiments, the growth substrate can be a fiber material of spoolable dimensions, thereby allowing formation of the carbon nanostructure to take place continuously on the growth subtract as the growth substrate is conveyed from a first location to a second location. The employed growth substrates can be in a variety of forms such as fibers, tows, yarns, woven and non-woven fabrics, sheets, tapes, belts, and the like. For convenience in continuous syntheses, tows, and yarns are particularly convenient fiber materials.

In some embodiments, the transition metal nanoparticles can be coated with an anti-adhesive coating that limits their adherence to the growth substrate. As discussed above, coating the transition metal nanoparticles with an anti-adhesive coating can also promote removal of the carbon nanostructure from the growth substrate following synthesis of the carbon nanostructure. Anti-adhesive coatings suitable for use in conjunction with coating the transition metal nanoparticles can include the same anti-adhesive coatings used for coating the growth substrate.

In various embodiments, the anti-adhesive coating can be carried along with the transition metal nanoparticles as the carbon nanostructure and the transition metal nanoparticles are removed from the growth substrate. In other embodiments, the anti-adhesive coating can be removed from the transition metal nanoparticles before or after they are incorporated into the carbon nanostructure. In still other embodiments, the transition metal nanoparticles can initially be incorporated into the carbon nanostructure and then subsequently removed. For example, in some embodiments, at least a portion of the transition metal nanoparticles can be removed from the carbon nanostructure by treating the carbon nanostructure with a mineral acid.

The carbon nanostructures can also be prepared by the continuous process as described in US 2014/0099493A1. The continuous process comprises (a) disposing a carbon nanotube-forming catalyst on a surface of a fiber material of spoolable dimensions; and (b) synthesizing carbon nanotubes directly on the fiber material, thereby forming a carbon nanostructure-laden fiber material. The formed carbon nanostructures can be removed from their growth substrates as a low-density carbon nanostructure flake or particulate material. The carbon nanotube (CNT) synthesis in the process can be based on a chemical vapor deposition (CVD) process and occurs at elevated temperatures. The specific temperature is a function of catalyst choice, but will typically be in a range from 500° C. to 1000° C. CVD-promoted nanotube growth on the catalyst-laden fiber material is then performed. The CVD process can be promoted by, for example, a carbon-containing feedstock gas such as acetylene, ethylene, methane, and/or propane. The CNT synthesis processes generally use an inert gas (nitrogen, argon, helium) as a primary carrier gas. The carbon feedstock is generally provided in a range from 0% to 50% of the total mixture. A substantially inert environment for CVD growth is prepared by removal of moisture and oxygen from the growth chamber. The catalyst used in the process can be prepared as a liquid solution that contains CNT-forming catalyst that contains transition metal nanoparticles. The operation of disposing a catalyst on the fiber material can be accomplished by spraying or dip coating the solution or by gas phase deposition via, for example, a plasma process.

The catalyst solution employed can be a transition metal nanoparticle which can be any d-block transition metal, as described above. In addition, the nanoparticles can include alloys and non-alloy mixtures of d-block metals in elemental form or in salt form, and mixtures thereof. Such salt forms include, without limitation, oxides, carbides, acetates, and nitrides. Non-limiting exemplary transition metal NPs include Ni, Fe, Co, Mo, Cu, Pt, Au, and Ag and salts thereof and mixtures thereof. In some embodiments, such CNT-forming catalysts are disposed on the fiber by applying or infusing a CNT-forming catalyst directly to the fiber material simultaneously with barrier coating deposition. Many of these transition metal catalysts are readily commercially available from a variety of suppliers, including, for example, Sigma Aldrich (St. Louis, Mo.) or Ferrotec Corporation (Bedford, N.H.).

Catalyst solutions used for applying the CNT-forming catalyst to the fiber material can be in any common solvent that allows the CNT-forming catalyst to be uniformly dispersed throughout. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNT-forming catalyst nanoparticles. Concentrations of CNT-forming catalyst can be in a range from about 1:1 to 1:10000 catalyst to solvent. Such concentrations can be used when the barrier coating and CNT-forming catalyst are applied simultaneously as well.

As described in US 2014/0099493A1, synthesizing carbon nanotubes on the fiber material can include numerous techniques for forming carbon nanotubes, including those disclosed in U.S. Patent Application Publication No. 2004/0245088A1, which is incorporated herein by reference. The CNS grown on the fibers can be formed by techniques such as, for example, micro-cavity, thermal or plasma-enhanced CVD techniques, laser ablation, arc discharge, and high pressure carbon monoxide (HiPCO). In some embodiments, any conventional sizing agents can be removed prior to CNT synthesis. In some embodiments, acetylene gas can be ionized to create a jet of cold carbon plasma for CNT synthesis. The plasma is directed toward the catalyst-bearing fiber material. Thus, in some embodiments for synthesizing CNS on a fiber material include (a) forming a carbon plasma; and (b) directing the carbon plasma onto the catalyst disposed on the fiber material. The diameters of the CNTs that are grown are dictated by the size of the CNT-forming catalyst as described above. In some embodiments, the sized fiber material is heated to between about 550° C. to about 800° C. to facilitate CNS synthesis. To initiate the growth of CNTs, two gases are bled into the reactor: a process gas such as argon, helium, or nitrogen, and a carbon-containing gas, such as acetylene, ethylene, ethanol or methane. CNTs grow at the sites of the CNT-forming catalyst.

Processes for rapid CNS growth on fiber materials allow for control of the CNT lengths with uniformity in continuous processes with spoolable fiber materials. With material residence times between 5 to 300 seconds, linespeeds in a continuous process for a system that is 3 feet long can be in a range anywhere from about 0.5 ft/min to about 36 ft/min and greater. The speed selected depends on various parameters as explained further below.

In some embodiments, a material residence time of about 5 seconds to about 30 seconds can produce CNTs having a length between about 1 micron to about 10 microns. In some embodiments, a material residence time of about 30 seconds to about 180 seconds can produce CNTs having a length between about 10 microns to about 100 microns. In still further embodiments, a material residence time of about 180 seconds to about 300 seconds can produce CNTs having a length between about 100 microns to about 500 microns.

In one embodiment of the present invention, the carbon nanostructures can be in the form of a flake material after being removed from the growth substrate upon which the carbon nanostructure is initially formed. As used herein, the term “flake material” refers to a discrete particle having finite dimensions, which is in a range from 1 nm to 35 μm thick, for example 10 nm to 20 μm, 50 nm to 10 μm or 100 nm to 1 μm, and in a range from 1 μm to 750 μm wide, for example 10 μm to 500 μm, 50 μm to 300 μm or 100 μm to 200 μm, including any value in between and any fraction thereof. The length of the flake material depends on the length of the growth substrate upon which the carbon nanostructure is initially formed. For example, in some embodiments, the length of the flake material can be in a range from 10 μm to 10 mm, for example 50 μm to 5 mm, or 100 μm to 1 mm, including any value in between and any fraction thereof.

In another embodiment of the present invention, the carbon nanostructures can be in the form of a pellet material after being removed from the growth substrate upon which the carbon nanostructure is initially formed. As used herein, the pellet material can have a length in a range from 0.5 mm to 20 mm, for example 1 mm to 10 mm, and a diameter in a range from 0.2 mm to 5 mm, for example 0.5 mm to 3 mm, including any value in between and any fraction thereof.

In preferred embodiments of the present invention, the carbon nanotubes contained in the carbon nanostructures can have a length from 1 μm to 500 μm, for example 10 μm to 300 μm, 30 μm to 200 μm, or 50 μm to 150 μm, and a diameter of from 1 to 20 nm, for example 5 to 10 nm, including any value in between and any fraction thereof.

The as-produced carbon nanostructures can have an initial bulk density ranging between 0.003 g/cm³ to 0.015 g/cm³ as measured according to ASTM D7481.

The carbon nanostructures have a carbon content of 95% by weight or greater, preferably 97% by weight or greater, for example, 95% by weight, 96% by weight, 97% by weight, 98% by weight, or 99% by weight. The carbon content can be measured via element analysis and determined by the ratio of the carbon weight to the sample weight, for example according to GBT 26752-2011. There is no difference in results between various element analysis methods.

For the purpose of the present invention, the carbon nanostructures having a specific surface area of 150 m²/g or greater, preferably 200 m²/g or greater as measured according to ASTM D6556 are particularly useful.

Examples of commercially available carbon nanostructures include, but are not limited to, ATHLOS™ series carbon nanostructures from Applied NanoStructured Solution, LLC, such as ATHLOS™ 100, ATHLOS™ 200 and ATHLOS™ SR1200.

The component (B) is present in the PBT composition according to the present invention in an amount of 0.2 to 10% by weight, for example 0.3, 0.5, 1, 2, 3, 4, 5, 6, 7, 8, 9, particularly in the range from 0.3 to 8% by weight, or 0.5 to 8% by weight, based on the total weight of the PBT composition.

In some embodiments, the PBT composition according to the present invention comprises carbon nanotubes alone as the component (B). In these embodiments, it is preferred that the component (B) is present in the PBT composition in an amount of 1 to 8% by weight, for example 2 to 7% by weight, 3 to 6% by weight, or 4 to 5% by weight, based on the total weight of the PBT composition.

In some other embodiments, the PBT composition according to the present invention comprises carbon nanostructures alone as the component (B). In these embodiments, it is preferred that the component (B) is present in the PBT composition in an amount of 0.2 to 5% by weight, for example 0.3 to 3% by weight, 0.4 to 2% by weight, or 0.5 to 1.5% by weight, based on the total weight of the PBT composition.

### Component (C)

Glass fiber is an inorganic non-metallic material with high mechanical strength, which is usually used as a reinforcing agent in plastic composite materials. Glass fiber is an amorphous material and generally has a softening point of 500° C. to 750° C., a boiling point of 1000° C. and a density of 2.4 to 2.76 g/cm³. Main components of glass fiber are silica, alumina, calcium oxide, boron oxide, magnesium oxide, sodium oxide, etc. Generally, glass fiber can be made of pyrophyllite, quartz sand, limestone, dolomite, borocalcite, or ascharite as raw materials through high-temperature melting, drawing, winding, weaving, etc.

The glass fiber can be employed in the form of long (endless) fiber or short fiber. In particular, the glass fiber is employed in the form of short fiber, which preferably has a length in the range from 2 to 50 mm, and a diameter in the range from 5 to 40 μm.

The glass fibers can have a cross section in the shape of circular, oval, elliptical, almost rectangular or rectangular, etc. If glass fibers with circular cross section are used as the component (C), the diameter of the glass fibers is preferably in the range from 5 to 40 μm, for example, from 10 to 20 μm. If glass fibers with non-circular cross section such as an elliptical cross section are used as the component (C), the dimensional ratio of the major cross-sectional axis to the minor cross-sectional axis is in particular higher than 2, preferably in the range from 2 to 8 and particularly preferably in the range from 3 to 5.

It is also possible to use a mixture of glass fibers with circular and non-circular cross section in the PBT compositions.

There is no particular restriction to the types of the glass fibers used herein. Any glass fibers prepared via known processes or any commercially available glass fibers suitable as reinforcing materials can be used for the purpose of the present invention. For example, the glass fibers include, but are not limited to, A, C, D, E, S, AR, ECR, ECT types of glass fibers. Particularly, glass fibers free of boron can be used. This type of glass fiber is commercially available, for example under the trade name of CPIC® ECS 3031H-3-H from Chongqing Polycomp International Corp.

The component (C), when present, can be in an amount of 1 to 50% by weight, for example 5 to 40% by weight, 10 to 35% by weight, or 20 to 30% by weight, based on the total weight of the PBT composition.

It is preferred that the PBT composition according to the present invention comprises the glass fibers. It has been surprisingly found that the glass fibers can advantageously improve the EMI shielding efficiency and reduce the resistivity of the PBT composition.

### Component (D)

The PBT composition according to the present invention can optionally comprise at least one additional conductive filler other than the conductive filler (B) as the component (D). The at least one additional conductive filler can for example be carbonaceous or metallic conductive filler. Suitable carbonaceous conductive fillers can include, but are not limited to carbon black powders and flakes, graphite powders and flakes, graphene powders and flakes, and carbon fibers. Suitable metallic conductive fillers can be selected from platinum group metal such as palladium (Pd) and platinum (Pt), transition metal such as cobalt, iron, nickel, silver, tin, copper, and any combinations thereof.

Carbon black powders and flakes, graphite powders and flakes, and carbon fibers are preferred as the component (D).

The component (D), when present, can be in an amount of 1 to 50% by weight, for example 1 to 35% by weight, 5 to 30% by weight, 10 to 25% by weight, or 20 to 25% by weight, based on the total weight the PBT composition.

### Component (E)

The PBT composition according to the present invention can optionally comprise at least one thermoplastic polymer other than PBT as the component (E).

The at least one thermoplastic polymer other than PBT can be selected from the group consisting of polypropylene (PP), polyethylene (PE), polycarbonate (PC), polyester other than PBT, polyamide, polyamide-imide, polyimide, polyetherimide, polyetheretherketone, polysulfone, aramid polymer, polyphenylene sulfide, polystyrene, polyvinyl chloride, polyvinylidene fluoride, polytetrafluoroethylene, polyvinyl alcohol, polyvinyl acetate, polyacrylonitrile, polyethyleneimine, acrylonitrile-butadiene-styrene copolymer, and any combination thereof.

It is preferred that polypropylene, polycarbonate, and/or polyester other than PBT can be used as the component (E).

The polyesters are generally derived from at least one glycol with at least one dicarboxylic acid or reactive equivalents thereof. The at least one glycol can be aliphatic, aromatic or in combination. The at least one dicarboxylic acid can be aromatic, cycloaliphatic dicarboxylic or in combination.

Examples of suitable aliphatic glycols include, but are not limited to, straight chain, branched, or cycloaliphatic alkylene glycols, such as ethylene glycol, 1,2-propylene glycol, 1,3-propylene glycol, 2-methyl-1,3-propandiol, 2,2-dimethyl-1,3-propane diol, 2-ethyl-2-methyl-1,3-propane diol, 1,3-pentane diol, 1,5-pentane diol, 2-methyl-1,5-pentane diol, 1,6-hexane diol, 1,4-cyclohexane dimethanol, triethylene glycol, dipropylene glycol and 1,10-decanediol. Examples of suitable aromatic glycols include, but are not limited to, resorcinol, hydroquinone, pyrocatechol, 1,5-naphthalene diol, 2,6-naphthalene diol, 1,4-naphthalene diol, 4,4′-dihydroxybiphenyl, bis(4-hydroxyphenyl)ether and bis(4-hydroxyphenyl)sulfone.

Examples of suitable aromatic dicarboxylic acids include, but are not limited to, terephthalic acid, phthalic acid, isophthalic acid, 1,4-naphthalenedicarboxylic acid, 1,5-naphthalene dicarboxylic acid, 2,6-naphthalene dicarboxylic acid. Examples of suitable cycloaliphatic dicarboxylic acids include, but are not limited to, norbornene dicarboxylic acid and 1,4-cyclohexane dicarboxylic acid. Suitable equivalents of dicarboxylic acids can include, but are not limited to, dialkyl or diaryl esters of dicarboxylic acids, for example dimethyl esters, anhydrides, salts and acid chlorides.

As the component (E), particularly useful polyesters can include polyalkylene terephthalates other than PBT such as polyethylene terephthalate (PET) and polytrimethylene terephthalate (PTT), polyalkylene naphthoates such as polyethylene naphthanoate (PEN) and polybutylene naphthanoate (PBN), polycycloalkylene terephthalates such as polycyclohexanedimethylene terephthalate (PCT). Preferably PET and PTT, especially PET can be used as the component (E).

The component (E), when present, can be in an amount of 1 to 40% by weight, for example, 5 to 35% by weight, or 10 to 30% by weight, based on the total weight of the PBT composition.

### Component (F)

The PBT composition according to the present invention can optionally comprise at least one additive as the component (F), for example release agents, reinforcing agents other than glass fibers, impact modifiers, thermostabilizers, compatibilizing agents, stabilizers, lubricants, antioxidants, photostabilizers, plasticizers, colorants such as dyes and/or pigments, surfactants, nucleating agents, coupling agents, antimicrobial agents, antistatic agents, and the like. The additives can be used in conventional amounts. For example, the PBT composition can comprise at least one additive in an amount of 0.01 to 15% by weight, based on the total weight of the PBT composition.

The PBT composition can for example comprise an impact modifier. Suitable impact modifiers can include polyolefin-based, styrene-based, unsaturated carboxylic acid-based impact modifiers. Suitable impact modifiers can also be those modified by a functional block, such as epoxy functional block and/or acid anhydride block. The epoxy function block can be units derived from a glycidyl (meth)acrylate. The acid anhydride block can be units derived from maleic anhydride.

Suitable polyolefin-based impact modifiers can include polyolefins comprising repeating units derived from olefin having 2 to 10 carbon atoms. Examples of such olefins include ethylene, 1-butene, 1-propylene, 1-pentene, 1-octene and mixture of ethylene and 1-octene, preferably ethylene, 1-propylene and mixture of ethylene and 1-octene.

Suitable unsaturated carboxylic acid-based impact modifiers can include blocks derived from carboxylic acid and derivatives thereof such as ester, imide and amide. Suitable carboxylic acid and derivatives thereof are for example acrylic acid, acrylic acid, methacrylic acid, maleic acid, fumaric acid, glutaconic acid, itaconic acid, citraconic acid, (meth)acrylate, methyl (meth)acrylate, ethyl (meth)acrylate, propyl (meth)acrylate, butyl (methyl)acrylate and isobutyl (meth)acrylate.

The impact modifier can also be a bi- or ter-polymer or a core-shell structure polymer. Examples of such impact modifier include styrene/ethylene/butylene copolymer (SEBS), ethylene-methyl acrylate-glycidyl methacrylate terpolymer, ethylene/propylene/diene rubber (EPDM) and ethylene-octene copolymer.

The impact modifier, when present, can be in an amount of 0.01 to 15% by weight, or 1 to 15% by weight, or 5 to 10% by weight, based on the total weight of the PBT composition.

The PBT composition can for example comprise a lubricant or a processing aid. Suitable lubricant or processing agent is preferably an ester or amide of saturated aliphatic carboxylic acids having from 10 to 40 carbon atoms and/or saturated aliphatic alcohols or amines having from 2 to 40 carbon atoms. The lubricant is preferably pentaerythritol esters of fatty acid having to 20 carbon atoms, more preferably pentaerythritol tetrastearate.

The lubricant, when present, can be in an amount of 0.01 to 3% by weight, or 0.1 to 2% by weight, or 0.3 to 1% by weight, based on the total weight of the PBT composition.

The PBT composition can for example comprise an antioxidant. Suitable antioxidants are aromatic amine-based antioxidants, hindered phenol-based antioxidants and phosphite-based antioxidants, particularly hindered phenol-based antioxidants. Examples of hindered phenol-based antioxidants include α-[3-[3,5-bis(1,1-dimethylethyl)-4-hydroxyphenyl]-1-oxopropyl]-ω-[3-[3,5-bis(1,1-dimethylethyl)-4-hydroxyphenyl]-1-oxopropoxy]poly(oxy-1,2-ethanediyl), 2,4-bis[(octylthio)methyl]-o-cresol, octyl-3,5-di-tert-butyl-4-hydroxy-hydrocinnamate, 3,5-bis(1,1-dimethylethyl)-4-hydroxybenzenepropanoic acid C7-C9-branched alkyl ester, 2,4-bis[(dodecylthio)methyl]-o-cresol, 4,4′-butylidene bis-(3-methyl-6-tert-butylphenol), 3,5-bis(1,1-dimethylethyl)-4-hydroxybenzenepropanoic acid octadecyl ester, pentaerythritol tetrakis(3-(3,5-di-tert-butyl-4-hydroxyphenyl)propionate), triethylene glycol bis[3-(3-tert-butyl-5-methyl-4-hydrophenyl)propionate], 2,4-bis(n-octylthio)-6-(4-hydroxy-3,5-di-tert-butylanilino)-1,3,5-triazine, tris-(3,5-di-tert-butyl-4-hydroxybenzyl)isocyanurate, 2,2-thiodiethylene bis[3-(3,5-di-tert-butyl-4-hydroxyphenyl)propionate].

The antioxidant, when present, can be in an amount of 0.001 to 2% by weight, or 0.01 to 1% by weight, or 0.2 to 0.8% by weight, based on the total weight of the PBT composition.

The PBT composition can for example comprise an adhesive adjuvant. Suitable adhesive adjuvants can be epoxides, for example epoxidized alkyl esters of fatty acid such as epoxidized linseed oil, epoxidized soybean oil and epoxidized rapeseed oil, and epoxy resins such as bisphenol-A resin.

The adhesive adjuvant, when present, can be in an amount of 0.01 to 3% by weight, or 0.1 to 2% by weight, or 0.2 to 1.5% by weight, based on the total weight of the PBT composition.

In a particular embodiment according to the present invention, the PBT composition comprises:
(A) 50 to 99% by weight of polybutylene terephthalate,
(B) 0.3 to 8% by weight of at least one conductive filler selected from the group consisting of carbon nanotubes, carbon nanostructures, and a combination thereof, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In one preferred embodiment, the PBT composition comprises:
(A) 60 to 99% by weight of polybutylene terephthalate,
(B) 0.5 to 8% by weight of at least one conductive filler selected from the group consisting of carbon nanotubes, carbon nanostructures, and a combination thereof, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In another particular embodiment according to the present invention, the PBT composition comprises:
(A) 50 to 99% by weight of polybutylene terephthalate,
(B) 0.2 to 5% by weight of carbon nanostructures, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In one preferred embodiment, the PBT composition comprises:
(A) 60 to 99% by weight of polybutylene terephthalate,
(B) 0.3 to 3% by weight of carbon nanostructures, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In another preferred embodiment, the PBT composition comprises:
(A) 60 to 99% by weight of polybutylene terephthalate,
(B) 0.4 to 2% by weight of carbon nanostructures, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In a further preferred embodiment, the PBT composition comprises:
(A) 60 to 99% by weight of polybutylene terephthalate,
(B) 0.5 to 1.5% by weight of carbon nanostructures, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In yet another particular embodiment according to the present invention, the PBT composition comprises:
(A) 50 to 99% by weight of polybutylene terephthalate,
(B) 0.2 to 5% by weight of carbon nanostructures, and
(C) 5 to 40% by weight of glass fiber,
each being based on the total weight of the polybutylene terephthalate composition,
wherein the carbon nanostructures each comprise a plurality of carbon nanotubes which are branched, crosslinked, and/or sharing common walls with one another.

In one preferred embodiment, the PBT composition comprises:
(A) 60 to 99% by weight of polybutylene terephthalate,
(B) 0.3 to 3% by weight of carbon nanostructures, and
(C) 10 to 35% by weight of glass fiber,
each being based on the total weight of the polybutylene terephthalate composition,
wherein the carbon nanostructures each comprise a plurality of carbon nanotubes which are branched, crosslinked, and/or sharing common walls with one another.

In another preferred embodiment, the PBT composition comprises:
(A) 60 to 80% by weight of polybutylene terephthalate,
(B) 0.4 to 2% by weight of carbon nanostructures, and
(C) 20 to 30% by weight of glass fiber,
each being based on the total weight of the polybutylene terephthalate composition,
wherein the carbon nanostructures each comprise a plurality of carbon nanotubes which are branched, crosslinked, and/or sharing common walls with one another.

In a further preferred embodiment, the PBT composition comprises:
(A) 60 to 80% by weight of polybutylene terephthalate,
(B) 0.5 to 1.5% by weight of carbon nanostructures, and
(C) 20 to 30% by weight of glass fiber,
each being based on the total weight of the polybutylene terephthalate composition,
wherein the carbon nanostructures each comprise a plurality of carbon nanotubes which are branched, crosslinked, and/or sharing common walls with one another.

In a more particular embodiment according to the present invention, the PBT composition comprises:
(A) 50 to 99% by weight of polybutylene terephthalate,
(B) 0.2 to 5% by weight of carbon nanostructures, and
(C) 5 to 40% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In one preferred embodiment, the PBT composition comprises:
(A) 60 to 99% by weight of polybutylene terephthalate,
(B) 0.3 to 3% by weight of carbon nanostructures, and
(C) 10 to 35% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In another preferred embodiment, the PBT composition comprises:
(A) 60 to 80% by weight of polybutylene terephthalate,
(B) 0.4 to 2% by weight of carbon nanostructures, and
(C) 20 to 30% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In a further preferred embodiment, the PBT composition comprises:
(A) 60 to 80% by weight of polybutylene terephthalate,
(B) 0.5 to 1.5% by weight of carbon nanostructures, and
(C) 20 to 30% by weight of glass fiber,
each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In a more particular embodiment according to the present invention, the PBT composition comprises:
(A) 50 to 99% by weight of polybutylene terephthalate, which preferably has an intrinsic viscosity in the range from 0.60 to 0.90 dL/g, as measured according to ISO 1628-5,
(B) 0.3 to 8% by weight of at least one conductive filler selected from the group consisting of carbon nanotubes, carbon nanostructures, and a combination thereof,
(C) 5 to 40% by weight of glass fiber, and
(D) optionally, 1 to 35% by weight of at least one additional conductive filler other than the conductive filler (B) selected from the group consisting of carbon black, carbon fiber, and graphite,
(E) optionally, 5 to 35% by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier;
each being based on the total weight of the polybutylene terephthalate composition,
wherein the carbon nanostructures each comprise a plurality of carbon nanotubes which are branched, crosslinked, and/or sharing common walls with one another.

In a preferred embodiment, the PBT composition comprises:
(A) 60 to 99% by weight of polybutylene terephthalate, which preferably has an intrinsic viscosity in the range from 0.60 to 0.90 dL/g, as measured according to ISO 1628-5,
(B) 0.5 to 8% by weight of at least one conductive filler selected from the group consisting of carbon nanotubes, carbon nanostructures, and a combination thereof,
(C) 10 to 35% by weight of glass fiber, and
(D) optionally, 10 to 25% by weight of at least one additional conductive filler other than the conductive filler (B) selected from the group consisting of carbon black, carbon fiber, and graphite,
(E) optionally, 5 to 35% by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier; each being based on the total weight of the polybutylene terephthalate composition,
wherein the carbon nanostructures each comprise a plurality of carbon nanotubes which are branched, crosslinked, and/or sharing common walls with one another, and
wherein the polybutylene terephthalate has an intrinsic viscosity in the range from 0.60 to 0.90 dL/g, preferably from 0.60 to 0.80 dL/g, as measured according to ISO 1628-5.

In a more particular embodiment according to the present invention, the PBT composition comprises:
(A) 50 to 99% by weight of polybutylene terephthalate, which preferably has an intrinsic viscosity in the range from 0.60 to 0.90 dL/g, as measured according to ISO 1628-5, (B) 0.2 to 5% by weight of carbon nanostructures,
(C) 10 to 35% by weight of glass fiber, and
(D) 10 to 25% by weight of at least one additional conductive filler other than the conductive filler (B) selected from the group consisting of carbon black, carbon fiber, and graphite, (E) optionally, 5 to 35% by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier; each being based on the total weight of the polybutylene terephthalate composition,
wherein the carbon nanostructures each comprise a plurality of carbon nanotubes which are branched, crosslinked, and/or sharing common walls with one another.

In one preferred embodiment, the PBT composition comprises:
(A) 60 to 99% by weight of polybutylene terephthalate, which preferably has an intrinsic viscosity in the range from 0.60 to 0.90 dL/g, as measured according to ISO 1628-5, (B) 0.3 to 3% by weight of carbon nanostructures,
(C) 20 to 30% by weight of glass fiber, and
(D) 10 to 25% by weight of at least one additional conductive filler other than the conductive filler (B) selected from the group consisting of carbon black, carbon fiber, and graphite,
(E) optionally, 5 to 35% by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier; each being based on the total weight of the polybutylene terephthalate composition,
wherein the carbon nanostructures each comprise a plurality of carbon nanotubes which are branched, crosslinked, and/or sharing common walls with one another.

In a further preferred embodiment, the PBT composition comprises:
(A) 60 to 80% by weight of polybutylene terephthalate, which preferably has an intrinsic viscosity in the range from 0.60 to 0.90 dL/g, as measured according to ISO 1628-5,
(B) 0.4 to 2% by weight of carbon nanostructures,
(C) 20 to 30% by weight of glass fiber, and
(D) 20 to 25% by weight of at least one additional conductive filler other than the conductive filler (B) selected from the group consisting of carbon black, carbon fiber, and graphite,
(E) optionally, 5 to 35 by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier; each being based on the total weight of the polybutylene terephthalate composition,
wherein the carbon nanostructures each comprise a plurality of carbon nanotubes which are branched, crosslinked, and/or sharing common walls with one another.

In another preferred embodiment, the PBT composition comprises:
(A) 60 to 80% by weight of polybutylene terephthalate, which preferably has an intrinsic viscosity in the range from 0.60 to 0.90 dL/g, as measured according to ISO 1628-5,
(B) 0.5 to 1.5% by weight of carbon nanostructures,
(C) 20 to 30% by weight of glass fiber, and
(D) 20 to 25% by weight of at least one additional conductive filler other than the conductive filler (B) selected from the group consisting of carbon black, carbon fiber, and graphite,
(E) optionally, 5 to 35% by weight of at least one thermoplastic polyester other than polybutylene terephthalate,
(F) optionally, 0.2 to 1.5% by weight of at least one adhesive adjuvant, and/or 0.3 to 1% by weight of at least one lubricant, and/or 5 to 10% by weight of at least one impact modifier; each being based on the total weight of the polybutylene terephthalate composition,
wherein the carbon nanostructures each comprise a plurality of carbon nanotubes which are branched, crosslinked, and/or sharing common walls with one another.

In all embodiments described herein, the sum of content of each component in the PBT composition is 100% by weight in total.

### EMI Shielding Articles

The PBT composition according to the present invention can be processed into various structures or forms by conventional methods to provide EMI shielding articles. For example, the PBT, the carbon nanotubes and/or carbon nanostructures and optionally the glass fiber, the at least one additional conductive filler, the thermoplastic polymer other than PBT and the additives can be mixed and then molded, for example via injection and/or extrusion to form an EMI shielding article.

It will be understood that all components of the PBT composition can be mixed at the same time. Alternatively, some components of the PBT composition can be pre-mixed and then mixed with other components.

It will also be understood that the additives can be incorporated as a separate component. Alternatively, in some cases that a commercially available PBT material already comprises some additives, such additives will be incorporated along with the PBT (A). It is also possible that the at least one additive is incorporated via both routes.

Accordingly, the present invention provides an EMI shielding article produced from the PBT composition according to the present invention. The EMI shielding article according to the present invention can have an EMI shielding efficiency of 4 dB or greater at 1 GHZ, 6 dB or greater at 1 GHZ, 9 dB or greater at 1 GHZ, 15 dB or greater at 1 GHz, 20 dB or greater at 1 GHZ, dB or greater at 1 GHz. Particularly, the EMI shielding article according to the present invention can have an EMI shielding efficiency of 6 dB to 50 dB, particularly 10 to 35 dB at 1 GHz, for example 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 dB.

In some embodiments, the EMI shielding article according to the present invention can have a surface resistivity of 1 to 500 Ohm/square (Q/u), 1 to 300 Ohm/square, 1 to 200 Ohm/square, 1 to 140 Ohm/square, particularly 1 to 80 Ohm/square, 1 to 50 Ohm/square, 1 to 20 Ohm/square or 1 to 10 Ohm/square.

Additionally or alternatively, the EMI shielding article according to the present invention can have a volume resistivity of 1 to 500 Ohm*cm (Ω·cm), 1 to 200 Ohm*cm, 1 to 100 Ohm*cm, 1 to 50 Ohm*cm, 1 to 35 Ohm*cm, particularly 2 to 15 Ohm*cm or 3 to 5 Ohm*cm.

It is preferred that the EMI shielding article according to the present invention can have a modulus of greater than 2,000 MPa, for example greater than 3,000 MPa, greater than 5,000 MPa, greater than 8,000 MPa, particularly a range from 3,000 to 24,000 MPa, or 10,000 to 20,000 MPa.

It is preferred that the EMI shielding article according to the present invention can have a elongation at break (%) of greater than 1, for example, greater than 3.

It is preferred that the EMI shielding article according to the present invention can have a Tensile strength at break of at least 30 MPa, for example at least 50 MPa, particularly a range from 30 to 500 MPa, 40 to 300 MPa, or 50 to 150 MPa.

It is preferred that the EMI shielding article according to the present invention can have a Charpy notched impact strength at 23° C. of at least 1 KJ/m², for example at least 2 KJ/m², particularly a range from 1 to 20 KJ/m², or 2 to 10 KJ/m².

The EMI shielding articles according to the present invention can be various electronic equipment components or housings. Examples include, but are not limited to radome, integrated circuit (IC) chip housing and camera sensor housing.

Particularly, the present invention provides a radome component produced from the polybutylene terephthalate composition according to the present invention, wherein the radome is preferably vehicle radome.

### Embodiments

Various embodiments are listed below. It will be understood that the embodiments listed below can be combined with all aspects and other embodiments in accordance with the scope of the invention.
1. A polybutylene terephthalate composition, comprising
(A) 40 to 99.8% by weight of polybutylene terephthalate,
(B) 0.2 to 10% by weight of at least one conductive filler selected from the group consisting of carbon nanotubes, carbon nanostructures, and a combination thereof, and
(C) 0 to 50% by weight of glass fiber,
each being based on the total weight of the polybutylene terephthalate composition,
wherein the carbon nanostructures each comprise a plurality of carbon nanotubes which are branched, crosslinked, and/or sharing common walls with one another.
2. The polybutylene terephthalate composition according to Embodiment 1, wherein the glass fiber is present in an amount of 1 to 50% by weight, preferably 5 to 40% by weight, more preferably 10 to 35% by weight, most preferably 20 to 30% by weight, based on the total weight of the polybutylene terephthalate composition.
3. The polybutylene terephthalate composition according to Embodiment 1 or 2, wherein the polybutylene terephthalate has an intrinsic viscosity in the range from 0.60 to 1.30 dL/g, preferably from 0.60 to 0.90 dL/g, more preferably from 0.60 to 0.80 dL/g, as measured according to ISO 1628-5.
4. The polybutylene terephthalate composition according to any of preceding Embodiments, wherein the polybutylene terephthalate is present in an amount of 50 to 99% by weight, for example, 60 to 99% by weight, 60 to 80% by weight, or 85 to 99% by weight, based on the total weight of the polybutylene terephthalate composition.
5. The polybutylene terephthalate composition according to any of preceding Embodiments, wherein the at least one conductive filler is present in an amount of 0.3 to 8% by weight, or 0.5 to 8% by weight, based on the total weight of the polybutylene terephthalate composition.
6. The polybutylene terephthalate composition according to Embodiment 5, wherein the carbon nanotubes are present in an amount of 1 to 8% by weight, for example, 2 to 7% by weight, 3 to 6% by weight, or 4 to 5% by weight, based on the total weight of the polybutylene terephthalate composition.
7. The polybutylene terephthalate composition according to Embodiment 5, wherein the carbon nanostructures are present in an amount of 0.2 to 5% by weight, for example, 0.3 to 3% by weight, 0.4 to 2% by weight, or 0.5 to 1.5% by weight, based on the total weight of the polybutylene terephthalate composition.
8. The polybutylene terephthalate composition according to any of preceding Embodiments, wherein the carbon nanostructures have an initial bulk density of 0.003 to 0.015 g/cm³, as measured according to ASTM D7481.
9. The polybutylene terephthalate composition according to any of preceding Embodiments, wherein the carbon nanostructures are branched and crosslinked carbon nanotube structures and have morphology of interlinked nanostructures.
10. The polybutylene terephthalate composition according to any of preceding Embodiments, wherein the carbon nanostructures each comprise a plurality of carbon nanotubes which are branched, crosslinked, and sharing common walls with one another.
11. The polybutylene terephthalate composition according to any of preceding Embodiments, wherein the polybutylene terephthalate composition further comprises at least one additional conductive filler other than the at least one conductive filler (B), which is carbonaceous or metallic, preferably carbonaceous.
12. The polybutylene terephthalate composition according to Embodiment 11, wherein the at least one additional conductive filler comprises carbon fibers, graphite powders or flakes, carbon black powders or flakes, graphene powders or flakes, or any combinations thereof.
13. The polybutylene terephthalate composition according to any of preceding Embodiments, wherein the polybutylene terephthalate composition further comprises at least one additive selected from the group consisting of release agents, reinforcing agents other than glass fibers, impact modifiers, thermostabilizers, compatibilizing agents, stabilizers, lubricants, antioxidants, photostabilizers, plasticizers, colorants such as dyes and/or pigments, surfactants, nucleating agents, coupling agents, antimicrobial agents, antistatic agents, and any combinations thereof.
14. An EMI shielding article produced from the polybutylene terephthalate composition according to any of Embodiments 1 to 13.
15. The EMI shielding article according to Embodiment 14, wherein the EMI shielding article is selected from radome, IC chip housing or camera sensor housing.
16. The EMI shielding article according to Embodiment 14 or 15, wherein the EMI shielding article has an EMI shielding efficiency of 4 dB or greater at 1 GHz, 6 dB or greater at 1 GHz, 9 dB or greater at 1 GHz, 15 dB or greater at 1 GHz, 20 dB or greater at 1 GHz, or 30 dB or greater at 1 GHz.
17. The EMI shielding article according to any of Embodiments 14 to 16, wherein the EMI shielding article has a surface resistivity of 1 to 500 Ohm/square, 1 to 300 Ohm/square, 1 to 200 Ohm/square, 1 to 140 Ohm/square, particularly 1 to 80 Ohm/square, 1 to 50 Ohm/square, 1 to 20 Ohm/square or 1 to 10 Ohm/square.
18. The EMI shielding article according to any of Embodiments 14 to 17, wherein the EMI shielding article has a volume resistivity of 1 to 500 Ω·cm, 1 to 200 Ω·cm, 1 to 100 Ω·cm, 1 to 50 Ω·cm, 1 to 35 Ω·cm, particularly 2 to 15 Ω·cm or 3 to 5 Ω·cm.

### Examples

Aspects of the present invention are more fully illustrated by the following examples, which are set forth to illustrate certain aspects of the present invention and are not to be construed as limiting thereof.

Following materials and test methods were used in the Examples.

### Materials:

(A) PBT: Ultradur® B1950 Nat (IV=0.75), Ultradur® B2550 (IV=0.88), Ultradur® B4500 (IV=1.08), commercially available from BASF, wherein IV is the intrinsic viscosity, as measured in a 0.005 g/ml phenol/1,2-dichlorobenzene solution (1:1 mass ratio) according to ISO 1628-5.
(B) Conductive filler
Carbon Nanotubes: GC30, commercially available from Shandong Dazhan Nano Materials Co., Ltd.;
Carbon Nanostructures: ATHLOS™ 200, commercially available from Applied NanoStructured Solution, LLC.
(C) Glass fiber: CPIC® ECS 3031H-3-H Boron Free, commercially available from Chongqing Polycomp International Corp.
(D) Additional conductive fillers
Carbon black: ENSACOR E260G, commercially available from Imerys Graphite & Carbon;
Graphite: TIMREX 20*50, commercially available from Imerys Graphite & Carbon;
Carbon Fiber: CFEPU C-6, commercially available from NPS Nippon Polymer Sangyo Co. Ltd.
(F) Additives
LOXIOL® P 861/3.5: commercially available from Emery Oleochemicals;
Lotader AX 8900: commercially available from Arkema;
Vikoflex 7190: commercially available from Arkema.

### Methods for Measurements:

1. EMI shielding efficiency was measured using a plate specimen with length of 150 mm, width of 150 mm and thickness of 2 mm at 1 GHz by Keysight Microwave Network Analyzer N5242B-425 in accordance with ASTM D4935-99.
2. Surface resistance (Rs, Ω/□) was determined by applying two lines of silver paint over one surface of a specimen of (60×60×2 mm) in a direction parallel to one side, with a length (L=60 mm) and a distance (d), measuring the resistance (R) with a multimeter with the probes on the middle point of each dried silver line, and calculated in accordance with Rs=R×L/d. The specimen is conditioned at 23° C. and 50% relative humidity (RH) for at least 4 hours before the measurement.
3. Volume resistance (Rv, Ohm*cm) was determined by applying a silver paint over both sides of width (W)×thickness (T) of a rectangular specimen with a length (L, cm), a width (W, cm) and a thickness (T, cm), measuring the resistance (R) with a multimeter with the probes on each dried silver surface, and calculated in accordance with Rv=R×(T×W)/L. The specimen is conditioned at 23° C. and 50% relative humidity (RH) for at least 4 hours before the measurement.
4. Tensile strength at break, elongation at break and tensile modulus were measured in accordance with ISO527-1-2012 using a specimen of type 1A.
5. Charpy notched impact strength was measured in accordance with ISO179-1/1eA-2010 at 23° C.
6. Thermal conductivities in plane and through plane, were measured by LFA 467 HyperFlash® from NETZSCH Analyzing & Testing in accordance with ASTM E1461-13.

### General Procedure for Preparing the EMI Shielding Test Specimens

EMI shielding test specimens were prepared in accordance with the formulations as shown in Table 1 and Table 2. The PBT and the additives were mixed together in a Turbula T50A high-speed stirrer and fed into a twin-screw extruder (Coperion ZSK18). The carbon nanotubes and/or carbon nanostructures, and glass fiber and at least one additional conductive filler when used were fed into the extruder at a downstream side feeder, and then melt-extruded with the zone temperatures ranging from 160° C. to 270° C. at a throughput of 8 kg/h, and pelletized, thus obtaining a PBT composition in a pellet form.

The dried pellets of the PBT composition were processed in an injection molding machine (KM130CX, from Krauss Maffei) with a clamping force of 130 T at melt temperatures of 265° C. to 275° C. to provide a test specimen.

The obtained test specimens were measured for the properties as described above. The test results and the formulations for the preparation of the test specimens are summarized in Table 1 and Table 2.

TABLE 1

| Component, wt. % | Comp. 1 | EX. 1 | EX. 2 | EX. 3 | EX. 4 | EX. 5 | EX. 6 |
|---|---|---|---|---|---|---|---|
| PBT Ultradur ® | | 94.7 | | | 98.2 | | |
| B4500 (IV = 1.08) | | | | | | | |
| PBT Ultradur ® | 68.2 | | 94.7 | 98.2 | | 76.2 | 62.7 |
| B1950 Nat (IV = | | | | | | | |
| 0.75) | | | | | | | |
| Carbon Nanotube | | 5 | 5 | | | | |
| GC30 | | | | | | | |
| ATHLOS ™ 200 | | | | 1.5 | 1.5 | 0.5 | 2 |
| Carbon | | | | | | | |
| Nanostructures | | | | | | | |
| Loxiol ® P861/3.5 | 0.3 | 0.3 | 0.3 | 0.3 | 0.3 | 0.3 | 0.3 |
| Lotader AX 8900 | 5 | | | | | 3 | 5 |
| Vikoflex 7190 | 1.5 | | | | | | |
| Carbon Fiber | 25 | | | | | | |
| CFEPU C-6 | | | | | | | |
| Glass Fiber CPIC ® | | | | | | 20 | 30 |
| ECS 3031H-3-H | | | | | | | |
| Boron Free | | | | | | | |
| Total percentage | 100 | 100 | 100 | 100 | 100 | 100 | 100 |

Properties

| | | | | | | | |
|---|---|---|---|---|---|---|---|
| Surface Resistivity, | 12 | 165 | 140 | 49 | 80.5 | 1.5 × | 23 |
| Ohm/sq | | | | | | 10⁵ | |
| Volume Resistivity, | 2.4 | 32 | 26 | 11 | 11.4 | 1.4 × | 5.0 |
| Ohm*cm | | | | | | 10⁴ | |
| Modulus, MPa | 19200 | 3490 | 3230 | 3370 | 3620 | 7830 | 11000 |
| Elongation at | 1.7 | 17 | 1.6 | 2.4 | 11 | 2.6 | 2.4 |
| break, % | | | | | | | |
| Tensile strength at | 156 | 69 | 49.4 | 56.9 | 75.9 | 127 | 136 |
| break, MPa | | | | | | | |
| Charpy notched | 7 | 3.3 | 1.9 | 2.8 | 5.8 | 8.2 | 7.2 |
| impact strength at | | | | | | | |
| 23° C., KJ/m² | | | | | | | |
| EMI shielding | 25.5 | 4 | 6 | 23.2 | 18.1 | 9 | 22 |
| efficiency at 1 GHz, dB | | | | | | | |
| Thermal | | | | 0.3285/0.2026 | | | |
| conductivity, | | | | | | | |
| In plane/through | | | | | | | |
| plane, W/m*K | | | | | | | |

EX.: Inventive Example;
Comp.: Comparative Example

As shown in Table 1, EX.1 and EX. 2 using carbon nanotube both show a desirable EMI shielding efficiency, electrically conductive properties and mechanical properties while EX. 2 shows relative higher EMI shielding efficiency than EX. 1 (6 dB of EX. 2 vs. 4 dB of EX. 1).

EX. 3 using carbon nanostructure shows much higher EMI shielding efficiency than EX. 2 (23.2 dB of EX. 3 vs. 6 dB of EX. 2), although the amount of carbon nanostructure used in EX. 3 was much lower than the amount of carbon nanotube used in EX. 2. EX. 3 also shows better surface resistivity, volume resistivity and mechanical properties compared to EX. 2. Furthermore, EX. 3 also shows good thermal conductivity.

Although the amount of carbon nanostructure used in EX. 3 was much lower than the amount of carbon fiber used in Comp. 1, EX. 3 still shows comparable EMI shielding efficiency compared to Comp. 1 (23.2 dB of EX. 3 vs. 25.5 dB of Comp. 1).

EX. 3 using low viscosity PBT (IV 0.75) shows relative higher EMI shielding efficiency than EX. 4 using middle viscosity PBT (IV 1.08) (23.2 dB of EX. 3 vs. 18.1 dB of EX. 4).

EX. 5 shows better EMI shielding efficiency (9 dB) than EX. 2 (6 dB), even though much lower amount of carbon nanostructure was used in EX. 5 compared to the CNT amount used in EX. 2. EX. 5 also shows that 30.8% of the EMI energy was absorbed by 3.2 mm plaque at 1 GHZ as measured according to ASTM D4935. Furthermore, EX. 5 also shows excellent mechanical properties, such as modulus, elongation at break, tensile strength at break, and Charpy notched impact strength.

EX. 6 shows much better EMI shielding efficiency (22 dB) than EX. 2 (6 dB), even though lower amount of carbon nanostructure was used in EX. 6 compared to the CNT amount used in EX. 2. Furthermore, EX. 6 also shows better EMI shielding efficiency and mechanical properties compared to EX. 5.

TABLE 2

| Component, wt. % | EX. 7 | EX. 8 | EX. 9 | EX. 10 |
|---|---|---|---|---|
| PBT Ultradur ® B2550 (IV = 0.88) | | | 45.2 | 25.2 |
| PBT Ultradur ® B1950 Nat (IV = 0.75) | 66.7 | 66.7 | | |
| ATHLOS ™ 200 Carbon Nanostructures | 1.5 | 1.5 | 1.5 | 1.5 |
| Loxiol ® P861/3.5 | 0.3 | 0.3 | 0.3 | 0.3 |
| Lotader AX 8900 | 5 | 5 | 3 | 3 |
| Vikoflex 7190 | 1.5 | 1.5 | | |
| Graphite TIMREX 20*50 (40% in Ultradur ® | | 25 | | |
| B4500) | | | | |
| Carbon Black ENSACOR E260G (30% in | | | 50 | 50 |
| Ultradur ® B4500) | | | | |
| Carbon Fiber CFEPU C-6 | 25 | | | |
| Glass Fiber CPIC ® ECS 3031H-3-H Boron Free | | | | 20 |
| Total percentage | 100 | 100 | 100 | 100 |

Properties

| | | | | |
|---|---|---|---|---|
| Surface Resistivity, Ohm/sq | 9.9 | 123 | 21.5 | 7.9 |
| Volume Resistivity, Ohm*cm | 3.0 | 31.6 | 5 | 2 |
| Modulus, MPa | 18500 | 4570 | 3390 | 8680 |
| Elongation at break, % | 1.2 | 2.5 | 2.2 | 1.1 |
| Tensile strength at break, MPa | 135 | 57 | 51.5 | 79.6 |
| Charpy notched impact strength at 23° C., KJ/m² | 5.3 | 2.8 | 2.8 | 4 |
| EMI shielding efficiency at 1 GHz, dB | 32 | 16.5 | 14.8 | 25 |
| Thermal conductivity, | | 0.6272/ | | |
| In plane/through plane, W/m*K | | 0.3233 | | |

EX.: Inventive Example;
Comp.: Comparative Example

As shown in Table 2, a combination of carbon nanostructure and carbon fiber was used in EX. 7, which shows much higher EMI shielding efficiency (32 dB) compared to Comp. 1 using carbon fiber alone (25.5 dB) and compared to EX. 3 (23.2 dB) using carbon nanostructure alone. Furthermore, EX. 7 also shows excellent mechanical properties, such as modulus, tensile strength at break, and Charpy notched impact strength.

A combination of carbon nanostructure and graphite was used in EX. 8. It was found that EX. 8 shows good EMI shielding efficiency, surface resistivity, volume resistivity, and mechanical properties. Furthermore, EX. 8 also shows higher thermal conductivity compared to EX. 3 using carbon nanostructure alone.

Both EX. 9 and EX. 10 show good EMI shielding efficiency, surface resistivity, volume resistivity, and mechanical properties. Furthermore, it is surprised that EX. 10 shows much higher EMI shielding efficiency and lower surface resistivity and volume resistivity due to the addition of glass fiber compared to EX. 9.

It will be apparent to one of ordinary skill in the art that various modifications and variations can be made in the present invention without departing from the scope or spirit of the present invention. It is intended that the embodiments and examples be considered as exemplary only. Thus, it is intended that the present invention covers such modifications and variations as come within the scope of the appended claims and their equivalents.

1. A polybutylene terephthalate composition, comprising:
(A) 40 to 99.8% by weight of polybutylene terephthalate,
(B) 0.2 to 10% by weight of at least one conductive filler selected from the group consisting of carbon nanotubes, carbon nanostructures, and a combination thereof, and
(C) 0 to 50% by weight of glass fiber,
each being based on a total weight of the polybutylene terephthalate composition,
wherein the carbon nanostructures each comprise a plurality of carbon nanotubes which are branched, crosslinked, and/or share common walls with one another.

2. The polybutylene terephthalate composition according to claim 1, wherein the glass fiber is present in an amount of 1 to 50% by weight, based on the total weight of the polybutylene terephthalate composition.

3. The polybutylene terephthalate composition according to claim 1, wherein the polybutylene terephthalate has an intrinsic viscosity in a range from 0.60 to 1.30 dL/g, as measured according to ISO 1628-5.

4. The polybutylene terephthalate composition according to claim 1, wherein the polybutylene terephthalate is present in an amount of 50 to 99% by weight, based on the total weight of the polybutylene terephthalate composition.

5. The polybutylene terephthalate composition according to claim 1, wherein the at least one conductive filler is present in an amount of 0.3 to 8% by weight, based on the total weight of the polybutylene terephthalate composition.

6. The polybutylene terephthalate composition according to claim 5, wherein the carbon nanotubes are present in an amount of 1 to 8% by weight, based on the total weight of the polybutylene terephthalate composition.

7. The polybutylene terephthalate composition according to claim 5, wherein the carbon nanostructures are present in an amount of 0.2 to 5% by weight, based on the total weight of the polybutylene terephthalate composition.

8. The polybutylene terephthalate composition according to claim 1, wherein the carbon nanostructures have an initial bulk density of 0.003 to 0.015 g/cm³, as measured according to ASTM D7481.

9. The polybutylene terephthalate composition according to claim 1, wherein the carbon nanostructures are branched and crosslinked carbon nanotube structures and have morphology of interlinked nanostructures.

10. The polybutylene terephthalate composition according to claim 1, wherein the carbon nanostructures each comprise a plurality of carbon nanotubes which are branched, crosslinked, and sharing common walls with one another.

11. The polybutylene terephthalate composition according to claim 1, wherein the polybutylene terephthalate composition further comprises at least one additional conductive filler other than the at least one conductive filler (B), which is carbonaceous or metallic.

12. The polybutylene terephthalate composition according to claim 11, wherein the at least one additional conductive filler comprises carbon fibers, graphite powders or flakes, carbon black powders or flakes, graphene powders or flakes, or any combinations thereof.

13. The polybutylene terephthalate composition according to claim 1, wherein the polybutylene terephthalate composition further comprises at least one additive selected from the group consisting of release agents, reinforcing agents other than glass fibers, impact modifiers, thermostabilizers, compatibilizing agents, stabilizers, lubricants, antioxidants, photostabilizers, plasticizers, colorants such as dyes and/or pigments, surfactants, nucleating agents, coupling agents, antimicrobial agents, antistatic agents, and any combinations thereof.

14. An EMI shielding article produced from the polybutylene terephthalate composition according to claim 1.

15. The EMI shielding article according to claim 14, wherein the EMI shielding article is radome, IC chip housing, or camera sensor housing.

16. The EMI shielding article according to claim 14, wherein the EMI shielding article has an EMI shielding efficiency of 4 dB or greater at 1 GHz.

17. The EMI shielding article according to claim 14, wherein the EMI shielding article has a surface resistivity of 1 to 500 Ohm/square.

18. The EMI shielding article according to claim 14, wherein the EMI shielding article has a volume resistivity of 1 to 500 Ω·cm.
